(19) United States
(12) Patent Application Publication
(10) Pub. No.: US 2025/0293224 A1
(43) Pub. Date: Sep. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shih-Ping CHANG, Taichung City (TW); Liang-Pin CHEN, Taichung City (TW)

(21) Appl. No.: 18/809,977

(22) Filed: Aug. 20, 2024

(30) Foreign Application Priority Data
Mar. 12, 2024 (TW) 113109038

(51) Int. Cl. H01L 25/18; H01L 23/00; H01L 23/31; H01L 23/498; H01L 23/538; H01L 25/00; H10B 80/00

(52) U.S. Cl. CPC H01L 25/18; H01L 24/14; H01L 24/16; H01L 24/24; H01L 24/25; H01L 24/73; H01L 25/50; H01L 23/3107; H01L 23/49811; H01L 23/5383; H01L 24/32; H01L 2224/1403; H01L 2224/16227; H01L 2224/24146; H01L 2224/2518; H01L 2224/32225; H01L 2224/73267; H10B 80/00

(57) ABSTRACT

An electronic package includes a first electronic component having a first active surface disposed in a first encapsulating layer; at least one second electronic component having a second active surface disposed in a second encapsulating layer; and an active electronic component having a third active surface disposed in a third encapsulating layer, the third active surface is electrically connected to and facing to the first active surface and the second active surface respectively, and the third active surface is directly electrically connected to the first active surface. By the implementation of the present invention, the signal transmission speed in the package can be accelerated by directly electrically connecting the active electronic component to the first electronic component disposed in the third and the first encapsulating layers respectively, and the work processing speed can be accelerated by assistant provided by the first electronic component.

### CROSS-REFERENCE TO RELATED APPLICATIONS

The present application is based upon and claims the right of priority to TW Patent Application No. 113109038, filed Mar. 12, 2024, the disclosure of which is hereby incorporated by reference herein in its entirety for all purposes.

### BACKGROUND

### 1. Technical Field

The present disclosure relates to a semiconductor packaging technology, and more particularly, to an electronic package and the manufacturing method thereof.

### 2. Description of Related Art

With the applications of High Performance Computing (HPC) technology in recent life, such as the application of development of cancer drugs or calculations of automatic sensing and detection of self-driving automobiles, are increasingly important and widespread, the packaging structures used in the electronic components of those fields are mostly the Fan-Out Package (FO PKG) structures, such as structures of the fan-out Multi-chip module (“FOMCM” in short) and FOEB (Fan-Out Embedded Bridge Die), etc., all of which have strong requirements of the designs of multiple chips, multiple redistribution layers, large fan-out size and high heat dissipation.

As shown in FIG. 1, in order to manufacture the aforementioned fan-out type packaging structure, a bridge chip 11 is embedded into a packaging structure 1, then a redistribution layer (RDL) 12 is disposed above the bridge chip 11, and then a functional chip 13 such as a Graphics Processing Unit (GPU) and a high bandwidth memory (HBM) 14 are disposed in the redistribution layer side by side or stacked on the redistribution layer by the industry. Thus, the functional chip 13 and the high bandwidth memory 14 can be communicated to each other through the bridge chip 11 to accomplish the requirement of signal transmission.

However, the connection method used in this conventional packaging structure 1 has to transmit signals between the functional chip and the high bandwidth memory through the bridge chip, such that the transmission speed of signals is limited by a longer transmission path and the performance of the bridge chip located upon the path, therefore it cannot meet the requirements of high-speed computing applied in various fields in the future.

Therefore, how to overcome the above-mentioned problems of conventional techniques has become an urgent issue to be solved.

### SUMMARY

In view of the aforementioned shortcomings of the prior art, the present disclosure provides an electronic package, comprising: a first electronic component having a first active surface and is disposed in a first encapsulating layer; at least one second electronic component having a second active surface and is disposed in a second encapsulating layer above the first encapsulating layer; and an active electronic component having a third active surface and is disposed in a third encapsulating layer above the second encapsulating layer, wherein the third active surface is electrically connected to and facing to the first active surface and the second active surface respectively, and the third active surface is directly electrically connected to the first active surface.

The present disclosure further provides a manufacturing method of an electronic package, comprising: disposing a first electronic component having a first active surface in a first encapsulating layer; disposing at least one second electronic component in a second encapsulating layer above the first encapsulating layer, wherein the second electronic component having a second active surface; and disposing an active electronic component having a third active surface in a third encapsulating layer above the second encapsulating layer, wherein the third active surface is electrically connected to and facing to the first active surface and the second active surface respectively, and the third active surface is directly electrically connected to the first active surface.

In the aforementioned electronic package and the manufacturing method thereof, a plurality of first connecting pads are disposed on the first active surface, and at least part of the first connecting pads are directly electrically connected to the third active surface.

In the aforementioned electronic package and the manufacturing method thereof, the first connecting pads are all directly electrically connected to the third active surface.

The aforementioned electronic package and the manufacturing method thereof further comprising a circuit structure, wherein the circuit structure is disposed between the at least one second electronic component and the active electronic component, the circuit structure has a first surface and a second surface opposing to each other and a circuit layer, and the third active surface of the active electronic component is electrically connected to the second active surface of the at least one second electronic component through the circuit layer.

In the aforementioned electronic package and the manufacturing method thereof, the active electronic component is disposed on and connected to the second surface of the circuit structure through the third active surface.

In the aforementioned electronic package and the manufacturing method thereof, the at least one second electronic component is disposed on and connected to the first surface of the circuit structure through the second active surface.

In the aforementioned electronic package and the manufacturing method thereof, the circuit layer includes a redistribution layer.

In the aforementioned electronic package and the manufacturing method thereof, the active electronic component is a graphics processing unit (GPU) or a central processing unit (CPU).

In the aforementioned electronic package and the manufacturing method thereof, the second electronic component is a memory chip or a memory module.

In the aforementioned electronic package and the manufacturing method thereof, the first electronic component is an auxiliary electronic component.

The aforementioned electronic package and the manufacturing method thereof further comprising a routing structure disposed beneath the first electronic component, and the routing structure is electrically connected to the first electronic component.

In the aforementioned electronic package and the manufacturing method thereof, the first electronic component is adhesively fixed to the routing structure through a die attach film (DAF).

In the aforementioned electronic package and the manufacturing method thereof, the second encapsulating layer and the first encapsulating layer are formed in the same material or in different materials.

In the aforementioned electronic package and the manufacturing method thereof, the third encapsulating layer and the second encapsulating layer are formed in the same material or in different materials.

It can be seen from above, in the electronic package and the manufacturing method thereof of the present disclosure, it mainly accelerates the transmission speed of signal within the package by making the active electronic component located in the third encapsulating layer directly electrically connected to the first electronic component (such as an auxiliary electronic component) located in the first encapsulating layer, and accelerates the work processing speed within the package with the assistance of the first electronic component (such as an auxiliary electronic component).

### BRIEF DESCRIPTION OF THE DRAWINGS

FIG. 1 is a schematic cross-sectional view of a conventional packaging structure.

FIG. 2A to FIG. 2F are the schematic cross-sectional views of embodiments of the manufacturing method of an electronic package of the present disclosure.

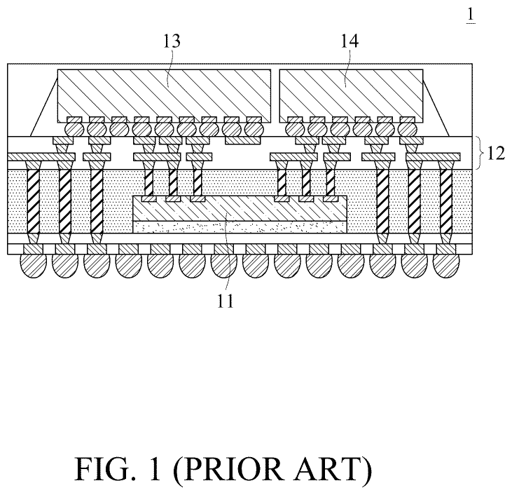

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

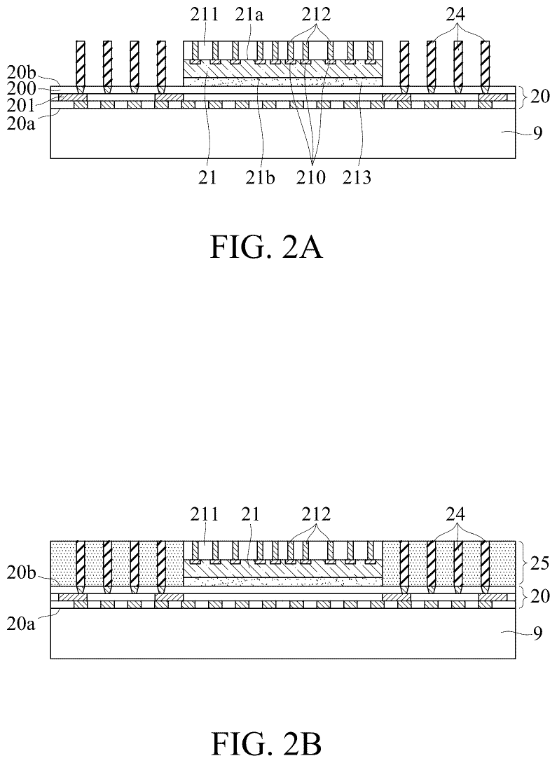

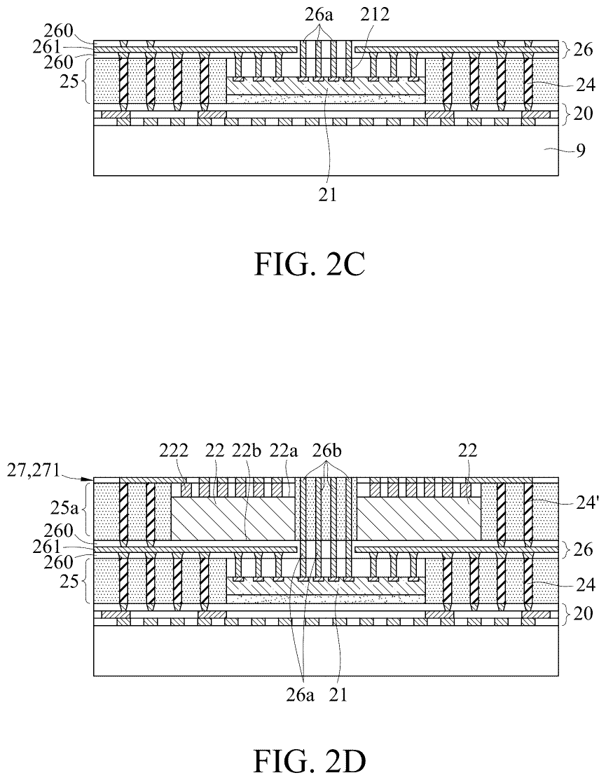

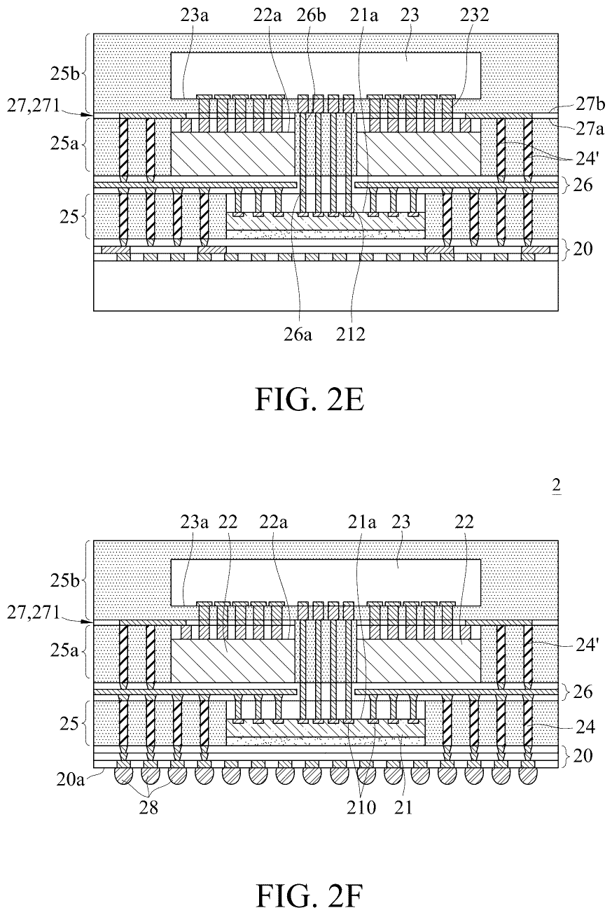

FIG. 2A to FIG. 2F are the schematic cross-sectional views of embodiments of the manufacturing method of an electronic package 2 of the present disclosure.

As shown in FIG. 2A, providing a first electronic component 21 at first, wherein the first electronic component 21 has a first active surface 21a and a first non-active surface 21b, and is disposed on a routing structure 20 on the surface of a carrier board 9 by its first non-active surface 21b. The routing structure 20 has a first side 20a and a second side 20b opposing to each other, and the routing structure 20 is bonded to the carrier board 9 with its first side 20a, where the first electronic component 21 is disposed on the second side 20b of the routing structure 20. Additionally, a plurality of conductive structures 24 electrically connected to the routing structure 20 are formed on the second side 20b of the routing structure 20, and a plurality of first conductors 212 electrically connected to the first electronic component 21 are formed on the first active surface 21a of the first electronic component 21.

The carrier board 9 is, for example, a plate body made of a semiconductor material or a glass material. The routing structure 20 has at least one dielectric layer 200 and a first circuit layer 201, such as a redistribution layer (RDL) form, disposed on the dielectric layer 200.

In an embodiment, the material for forming the circuit layer 201 is, for example copper, and the material for forming the dielectric layer 200 is a dielectric material such as Polybenzoxazole (PBO), Polyimide (PI), Prepreg (PP), etc.

The first electronic component 21 may be an active element, a passive element or a combination of them, wherein the active element is, for example, a semiconductor chip, and the passive element is, for example, a resistor, a capacitor, and an inductor, or the first electronic component 21 may have no electrical function and is electrically connected to the electrical element formed subsequently above it.

In an embodiment, the first electronic component 21 is a semiconductor chip. The first electronic component 21 has a first active surface 21a and a first non-active surface 21b opposing to each other, and is adhesively fixed to the second side 20b of the routing structure 20 with its first non-active surface 21b through a glue material or a die attach film (DAF) 213, and the first active surface 21a has a plurality of first connecting pads 210, such that the first conductor 212 is formed on the first connecting pad 210, and an insulating layer 211 is formed on the first active surface 21a, such that the insulating layer 211 covers the first connecting pads 210 and the first conductors 212. Alternatively, the first conductors 212 may be exposed from the insulating layer 211.

In an embodiment, the first conductor 212 is, for example, a copper pillar, but can also be a columnar body made in a metal such as a solder bump, and is not specified.

The conductive structures 24 are disposed on and electrically connected to the first circuit layer 201. In an embodiment, the conductive structure 24 is a columnar body, and its material is a metal such as copper or solder material.

As shown in FIG. 2B, forming a first encapsulating layer 25 on second side 20b of the routing structure 20, such that the first encapsulating layer 25 covers the first electronic component 21, the insulating layer 211 (or the first conductors 212) and the conductive structures 24, then to make the upper surface of the first encapsulating layer 25 flush with the upper surface of the insulating layer 211, the end surfaces of the conductive structures 24 and the end surfaces of the first conductors 212 by a leveling process, so that the upper surface of the insulating layer 211, the end surfaces of the conductive structures 24 and the end surfaces of the first conductors 212 are exposed from the first encapsulating layer 25.

In an embodiment, the material for forming the first encapsulating layer 25 is an insulating material such as polyimide (PI), dry film, epoxy, or molding compound, but is not limited to the above.

Furthermore, the first encapsulating layer 25 can be formed on the second side 20b of the routing structure 20 by lamination or molding.

In addition, the leveling process removes part of material of the conductive structure 24, part of material of the insulating layer 211 (and part of material of the first conductor 212 according to the requirement) and part of material of the first encapsulating layer 25 by grinding.

It should be understood that if the first conductor 212 has been exposed from the insulating layer 211, then the first conductors 212 can be exposed from the first encapsulating layer 25 by removing part of material of the insulating layer 211 (and removing part of material of the insulating layer 211 and part of material of the first conductor 212 to make the first conductors 212 to be exposed from the first encapsulating layer 25 according to requirement).

As shown in FIG. 2C, forming a middle circuit structure 26 on the first encapsulating layer 25, and making the middle circuit structure 26 electrically connected to the routing structure 20 through a plurality of conductive structures 24. In addition, a plurality of first conductive pillars 26a are formed in the middle circuit structure 26, wherein each of the first conductive pillars 26 is correspondingly joined and electrically connected to one of the first conductors 212. The material of the first conductive pillar 26a may be same as the material of the first conductor 212, such as a copper pillar.

In an embodiment, the middle circuit structure 26 includes a middle dielectric layer 260 and a middle circuit layer 261 (such as RDL), and the middle circuit layer 261 is electrically connected to the routing structure 20 beneath the middle circuit layer 261 through a plurality of conductive structures 24.

Furthermore, the material for forming the middle circuit layer 261 is copper, and the material for forming the middle dielectric layer 260 is a dielectric material such as PBO, PI or PP.

As shown in FIG. 2D, next providing at least one second electronic component 22. In an embodiment, providing two second electronic components 22 for example. The second electronic components 22 has a second active surface 22a and a second inactive surface 22b respectively, and these second electronic components 22 are disposed on the middle circuit structure 26 above the first encapsulating layer 25 with their second non-active surfaces 22b respectively. Conductive structures 24′ connecting to the middle circuit structure 26 may be formed beside the second electronic components 22. Then the second electronic components 22 and the conductive structures 24′ are encapsulated with an encapsulant material to form a second encapsulating layer 25a.

Each second electronic component 22 is disposed over the first encapsulating layer 25 with its second active surface 22a facing up, then the second electronic components 22 and the conductive structures 24′ are encapsulated with an encapsulant material to form the second encapsulating layer 25a. Next, a circuit structure 27 is formed on the second encapsulating layer 25a.

The conductive structures 24′ are disposed between the middle circuit structure 26 and the circuit structure 27 and are electrically connected with the middle circuit layer 261 and the circuit structure 27, and the conductive structures 24′ are columnar bodies made of a metal such as copper or of a solder material.

The material of the encapsulant material is an insulating material such as polyimide (PI), dry film, epoxy or molding compound, but is not limited to the above. For instance, the encapsulant material may be formed on the middle circuit structure 26 by lamination or molding. It should be understood that the encapsulant material and the material of the first encapsulating layer 25 may be same or different.

The middle circuit structure 26 includes a plurality of middle dielectric layers 260 and a middle circuit layer 261 (such as RDL) disposed on the middle dielectric layer 260. For instance, the material for forming the middle circuit layer 261 is copper, and the material for forming the middle dielectric layer 260 is a dielectric material such as PBO, PI, PP, etc.

The second electronic component 22 may be an active element, a passive element or a combination of them. The active element is, for example, a semiconductor chip such as Dynamic Random Access Memory (DRAM), etc. The passive element is, for example, a resistor, capacitor or inductor. In this embodiment, the two second electronic components 22 are High Bandwidth Memory (HBM) chips or modules, but there is no special limitation in the present disclosure.

The second active surface 22a of each the second electronic component 22 has a plurality of electrode pads (not shown) that are electrically connected to the circuit layer 271 (such as redistribution layer) of the circuit structure 27 through a plurality of second conductors 222 such as solder bumps, copper bumps or other bumps, etc. The encapsulant material can covers the second electronic component 22 and the second conductors 222 at the same time. In addition, a plurality of second conductive pillars 26b are formed in the second encapsulating layer 25a, wherein each second conductive pillar 26b correspondingly joined and electrically connected to each first conductive pillars 26a. The material of the second conductive pillars 26b may be the same to the material of the first conductive pillars 26a, for example, copper pillars.

Furthermore, part of the electrode pads of the two second electronic components 22 can be mutually electrically connected to the first electronic component 21 through the circuit structure 27, the middle circuit structure 26 and the conductive structures 24′.

Next, covering the second electronic components 22 and the conductive structures 24′ with the encapsulant material to form the form the second encapsulating layer 25a. It can be understood that the material constituting the second encapsulating layer 25a may be same or different to the material constituting the first encapsulating layer 25.

As shown in FIG. 2E, next providing an active electronic component 23. The active electronic component 23 has a third active surface 23a, and is disposed on the circuit structure 27 with its third active surface 23a through a plurality of third conductors 232 in the manner that the third active surface 23a faces to the first electronic component 21 and the second electronic components 22, and the third active surface 23a is electrically connected to and faces to the first active surface 21a and the second active surface 22a respectively. The third active surface 23a and the first active surface 21a are directly electrically connected to the third conductors 232, the second conductive pillars 26b, the first conductive pillars 26a and the first conductor 212. Thus, signals can be transmitted between the active electronic component 23 and the first electronic component 21 directly without other components such as bridge chips or circuit structures, etc., therefore the transmission speed of signals between the active electronic component 23 and the first electronic component 21 can be accelerated.

The active electronic component 23 is, for example, a graphics processing unit or a central processing unit. In this embodiment, the active electronic component 23 is a graphics processing unit.

After the active electronic component 23 has been disposed, the active electronic component 23 can be encapsulated with an encapsulant material to form a third encapsulating layer 25b. The material for forming the third encapsulating layer 25b is an insulating material such as polyimide (PI), dry film, epoxy or molding compound, etc., but is not limited to the above. It can be understood that the material for forming the third encapsulating layer 25b may be same or different to the material for forming the second encapsulating layer 25a.

As shown in FIG. 2F, removing the carrier board 9 to expose the first side 20a of the routing structure 20, then an electronic package 2 can be obtained. In a variant embodiment, a ball placement process may be performed on the first side 20a further after removing the carrier board 9 to form a plurality of solder balls 28 on the bottom surface of the routing structure 20.

More descriptions of some details of the embodiment of the manufacturing method of the electronic package will be provided as follows.

Generally speaking, at least part of the plurality of the first connecting pads 210 on the first active surface 21a are directly electrically connected to the third active surface 23a. In some embodiments, the first connecting pads 210 are all directly electrically connected to the third active surface 23a, just according to the requirement of the design, and has no special limitation in the present disclosure.

In the aforementioned electronic package and the manufacturing method thereof, the active electronic component 23 is disposed on and connected to the second surface 27b of the circuit structure 27 through the third active surface 23a.

In some embodiments, the at least one second electronic component 22 is disposed on and connected to the first surface 27a of the circuit structure 27 through the second active surface 22a.

In some embodiments, the at least one circuit layer 271 includes a redistribution layer.

In some embodiment, the first electronic component 21 is an auxiliary electronic component.

This embodiment also discloses an electronic package 2, comprising: a first electronic component 21 having a first active surface 21a and is disposed in a first encapsulating layer 25; at least one second electronic component 22 having a second active surface 22a and is disposed in a second encapsulating layer 25a above the first encapsulating layer 25; and an active electronic component 23 having a third active surface 23a and is disposed in a third encapsulating layer 25b above the second encapsulating layer 25a, wherein the third active surface 23a is electrically connected to and facing to the first active surface 21a and the second active surface 22a respectively, and the third active surface 23a is directly electrically connected to the first active surface 21a.

In some embodiments, a plurality of first connecting pads 210 are disposed on the first active surface 21a, and at least part of the first connecting pads 210 are directly electrically to the third active surface 23a.

In some embodiments, the first connecting pads 210 are all directly electrically connected to the third active surface 23a.

In some embodiments, it further comprises a circuit structure 27, wherein the circuit structure 27 is disposed between the at least one second electronic component 22 and the active electronic component 23, and the circuit structure 27 has a first surface 27a and a second surface 27b opposing to each other and at least one circuit layer 271, and the third active surface 23a of the active electronic component 23 is electrically connected to the second active surface 22a of the at least one second electronic component 22 through the circuit layer 271.

In some embodiments, the active electronic component 23 is disposed on and connected to the second surface 27b of the circuit structure 27 through the third active surface 23a.

In some embodiments, the at least one second electronic component 22 is disposed on and connected to the first surface 27a of the circuit structure 27 through the second active surface 22a.

In some embodiments, the at least one circuit layer 271 includes a redistribution layer.

In some embodiments, the active electronic component 23 is a graphics processing unit or a central processing unit.

In some embodiments, the second electronic component 22 is a memory chip or a memory module.

In some embodiments, the first electronic component 21 is an auxiliary electronic component.

In some embodiments, it further comprises a routing structure 20 disposed beneath the first electronic component 21, and the routing structure 20 is electrically connected to the first electronic component 21.

In some embodiments, the first electronic component 21 is adhesively fixed to the routing structure through a die attach film 213.

In some embodiments, the second encapsulating layer 25a and the first encapsulating layer 25 are formed in the same material.

In some embodiments, the third encapsulating layer 25b and the second encapsulating layer 25a are formed in the same material.

In summary, in the electronic package and the manufacturing method thereof of the present disclosure, it mainly accelerates the transmission speed of signal within the package by making that the first electronic component (or the auxiliary electronic component) located in the first encapsulating layer in the lower part of the package and/or the second electronic component located in the second encapsulating layer in the middle part of the package can be directly electrically connected to the active electronic component located in the third encapsulating layer in the upper part of the package respectively. Also since the active electronic component can be directly electrically connected to the first electronic component and/or the second electronic component, such that there is no need to dispose a bridge element within the conventional packaging structure, so the auxiliary electronic component can be provided to assist work processing within the package, thereby the overall efficiency of the electronic package can be further improved.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a first electronic component having a first active surface and disposed in a first encapsulating layer;
at least one second electronic component having a second active surface and disposed in a second encapsulating layer above the first encapsulating layer; and
an active electronic component having a third active surface and disposed in a third encapsulating layer above the second encapsulating layer, wherein the third active surface is electrically connected to and facing to the first active surface and the second active surface respectively, and the third active surface is directly electrically connected to the first active surface.

2. The electronic package of claim 1, wherein a plurality of first connecting pads are disposed on the first active surface, and at least part of the first connecting pads are directly electrically connected to the third active surface.

3. The electronic package of claim 2, wherein the first connecting pads are all directly electrically connected to the third active surface.

4. The electronic package of claim 1 further comprising a circuit structure, wherein the circuit structure is disposed between the at least one second electronic component and the active electronic component, and has a first surface and a second surface opposing to each other and a circuit layer, and the third active surface of the active electronic component is electrically connected to the second active surface of the at least one second electronic component through the circuit layer.

5. The electronic package of claim 4, wherein the active electronic component is disposed on and connected to the second surface of the circuit structure through the third active surface.

6. The electronic package of claim 4, wherein the at least one second electronic component is disposed on and connected to the first surface of the circuit structure through the second active surface.

7. The electronic package of claim 4, wherein the circuit layer includes a redistribution layer.

8. The electronic package of claim 1, wherein the active electronic component is a graphics processing unit or a central processing unit.

9. The electronic package of claim 1, wherein the second electronic component is a memory chip or a memory module.

10. The electronic package of claim 1, wherein the first electronic component is an auxiliary electronic component.

11. The electronic package of claim 1 further comprising a routing structure disposed beneath the first electronic component, and the routing structure is electrically connected to the first electronic component.

12. The electronic package of claim 11, wherein the first electronic component is adhesively fixed to the routing structure through a die attach film.

13. A manufacturing method of an electronic package, comprising:
disposing a first electronic component having a first active surface in a first encapsulating layer;
disposing at least one second electronic component in a second encapsulating layer above the first encapsulating layer, wherein the second electronic component has a second active surface; and
disposing an active electronic component having a third active surface in a third encapsulating layer above the second encapsulating layer, wherein the third active surface is electrically connected to and facing to the first active surface and the second active surface respectively, and the third active surface is directly electrically connected to the first active surface.

14. The manufacturing method of claim 13, wherein a plurality of first connecting pads are disposed on the first active surface, and at least part of the first connecting pads are directly electrically connected to the third active surface.

15. The manufacturing method of claim 14, wherein the first connecting pads are all directly electrically connected to the third active surface.

16. The manufacturing method of claim 13 further comprising disposing a circuit structure between the at least one second electronic component and the active electronic component, wherein the circuit structure has a first surface and a second surface opposing to each other and a circuit layer, and the third active surface of the active electronic component is electrically connected to the second active surface of the at least one second electronic component through the circuit layer.

17. The manufacturing method of claim 16, wherein the active electronic component is disposed on and connected to the second surface of the circuit structure through the third active surface.

18. The manufacturing method of claim 16, wherein the at least one second electronic component is disposed on and connected to the first surface of the circuit structure through the second active surface.

19. The manufacturing method of claim 16, wherein the circuit layer includes a redistribution layer.

20. The manufacturing method of claim 13, wherein the active electronic component is a graphics processing unit or a central processing unit.

21. The manufacturing method of claim 13, wherein the second electronic component is a memory chip or a memory module.

22. The manufacturing method of claim 13, wherein the first electronic component is an auxiliary electronic component.

23. The manufacturing method of claim 13 further comprising providing a carrier structure and a routing structure, wherein the routing structure is disposed on the carrier structure and is electrically connected to the first electronic component.

24. The manufacturing method of claim 23, wherein the first electronic component is adhesively fixed on the routing structure through a die attach film.
